(19) United States
(12) Patent Application Publication
(10) Pub. No.: US 2009/0124048 A1
(43) Pub. Date: May 14, 2009

(54) Semiconductor device and method of manufacturing semiconductor device

(75) Inventor: Masahiro Sekiguchi, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 12/289,248

(22) Filed: Oct. 23, 2008

Related U.S. Application Data
(62) Division of application No. 11/239,421, filed on Sep. 30, 2005, now abandoned.

(30) Foreign Application Priority Data
Sep. 30, 2004 (JP) P2004-286368

(51) Int. Cl. H01L 21/50

(52) U.S. Cl. 438/110; 257/E21.499; 438/118

(57) ABSTRACT

A semiconductor device is configured of a semiconductor chip which is sandwiched by first and second resin films having a wiring pattern. Plural semiconductor chips can be fabricated collectively by sandwiching the semiconductor chips by the first and second resin films, and productivity can be improved.

### CROSS-REFERENCE TO RELATED APPLICATIONS

This application is based upon and claims the benefit of priority from the prior Japanese Patent Application No. 2004-286368, filed on Sep. 30, 2004; the entire contents of which are incorporated herein by reference.

### BACKGROUND OF THE INVENTION

1. Field of the Invention

The present invention relates to a semiconductor device which can have semiconductor wafers fabricated collectively by using a resin film and a method of manufacturing it.

2. Description of the Related Art

A semiconductor device comprising semiconductor elements mounted on a wiring board is generally manufactured as follows. Specifically, a semiconductor element is picked up from diced semiconductor wafers of silicon or the like for each element and mounted on a film substrate on which a wiring pattern is formed or a wiring board such as a printed circuit board. For example, a semiconductor device (FC-BGA) which is flip-chip connected has a semiconductor element having stud bumps formed flip-chip connected onto a substrate, on which a wiring pattern is formed, for each element.

There is disclosed a technology of a method of manufacturing a semiconductor chip as follows. Specifically, a wafer is adhered to a sheet, and first cutting is conducted. And, a gap formed by the first cutting is increased by stretching the sheet, a mold resin is charged in it, and second cutting is conducted to form the same gap as that formed by the first cutting (Japanese Patent Laid-Open Application No. 2000-21906).

### SUMMARY OF THE INVENTION

A conventional method of manufacturing a semiconductor package separately handles semiconductor elements, so that handling is difficult, and productivity might be degraded.

The present invention has been made in view of the above circumstances and provides a semiconductor device of which productivity can be improved and a method of manufacturing it.

According to an aspect of the present invention, there is provided a semiconductor device, comprising a semiconductor chip; first and second resin films which hold the semiconductor chip between them; a first wiring pattern which is disposed on the first resin film and electrically connected to the semiconductor chip; a second wiring pattern which is disposed on the second resin film; and external connection terminals which are disposed on the second resin film and electrically connected to the second wiring pattern.

According to another aspect of the present invention, there is provided a method of manufacturing a semiconductor device, comprising applying tension to a stretchable adhesive sheet, on which plural semiconductor chips are disposed, to separate the plural semiconductor chips from one another; adhering a first resin film to the plural semiconductor chips and curing it; removing the adhesive sheet from the plural semiconductor chips; adhering a second resin film to the plural semiconductor chips and curing it; and forming first and second wiring patterns on the first and second resin films respectively.

### BRIEF DESCRIPTION OF THE DRAWINGS

FIG. 1 is a sectional view of a semiconductor device according to a first embodiment of the present invention.

FIG. 2 is a flow chart of a manufacturing process of the semiconductor device according to the first embodiment.

FIG. 3A and FIG. 3B are perspective views of semiconductor chips in the manufacturing process of the semiconductor device according to the first embodiment.

FIG. 4A through FIG. 4D are sectional views of the semiconductor chips in the manufacturing process of the semiconductor device according to the first embodiment.

FIG. 5A through FIG. 5D are sectional views of the semiconductor chips in the manufacturing process of the semiconductor device according to the first embodiment.

FIG. 6 is a sectional view of the semiconductor chips in the manufacturing process of the semiconductor device according to the first embodiment.

FIG. 7 is a sectional view of a semiconductor device according to a second embodiment of the present invention.

FIG. 8 is a sectional view of a semiconductor device according to a third embodiment of the present invention.

### DESCRIPTION OF THE EMBODIMENTS

### First Embodiment

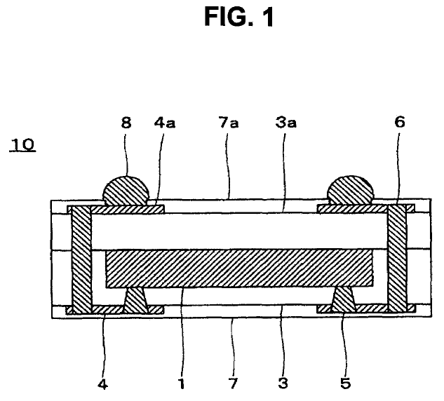

A semiconductor device 10 according to the first embodiment of the present invention will be described with reference to FIG. 1.

As shown in FIG. 1, the semiconductor device 10 is formed of, for example, a silicon semiconductor and has a chip-like semiconductor element 1 (semiconductor chip) with a thickness of, for example, about 60 μm. The semiconductor element 1 is sandwiched between and coated with first and second wiring resin films 3, 3a. For the first and second wiring resin films 3, 3a, the same material as that of a build-up layer, such as an epoxy-based thermosetting resin film, can be used. A wiring pattern is formed on the build-up layer and disposed on the surface of a core substrate of a build-up wiring board. Wiring patterns 4, 4a including lands and the like are formed on the surfaces of the first and second wiring resin films 3, 3a.

The wiring patterns 4, 4a are formed on the surfaces of the first and second wiring resin films 3, 3a. The wiring pattern 4 is formed on the surface of the semiconductor element 1 and electrically connected to a connection electrode (not shown) which is electrically connected to an internal circuit (not shown) of the semiconductor element 1. External connection terminals 8 such as solder balls are formed on the connection electrode portions of the wiring pattern 4a. The wiring patterns 4, 4a are electrically connected through a connection wiring 6 formed of a plated layer or the like buried in through holes formed in the first wiring resin film 3. As a result, the external connection terminals 8 are electrically connected to the internal circuit of the semiconductor element 1 via the wiring patterns 4, 4a.

Insulating films 7, 7a such as a resist are formed on the surfaces of the first and second wiring resin films 3, 3a to cover the wiring patterns 4, 4a excepting the external connection terminals 8.

The semiconductor device according to this embodiment has the semiconductor element sandwiched between the wiring resin films. Thus, a new package structure can be obtained, and the semiconductor device can be made thinner furthermore.

### (Manufacturing Process)

Then, the manufacturing process according to this embodiment will be described.

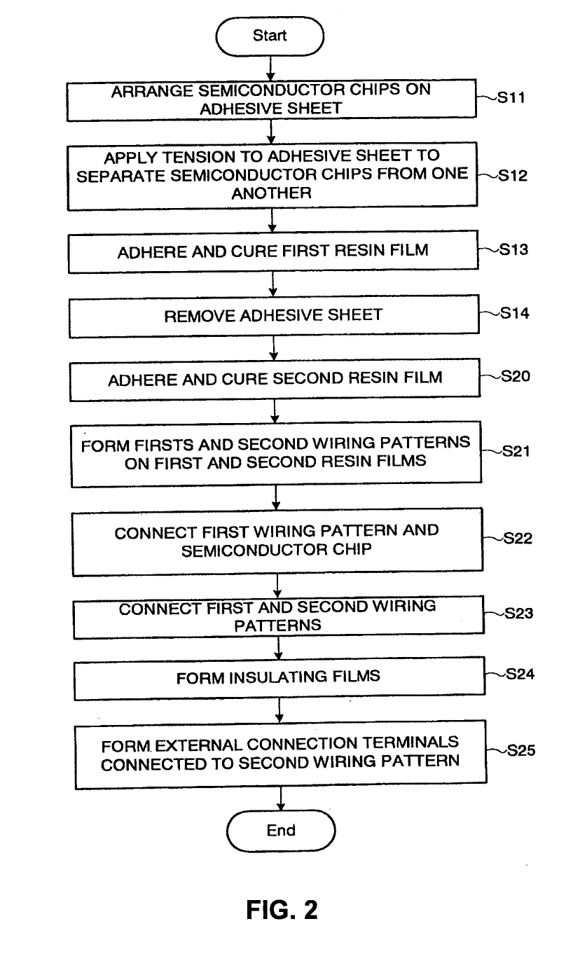

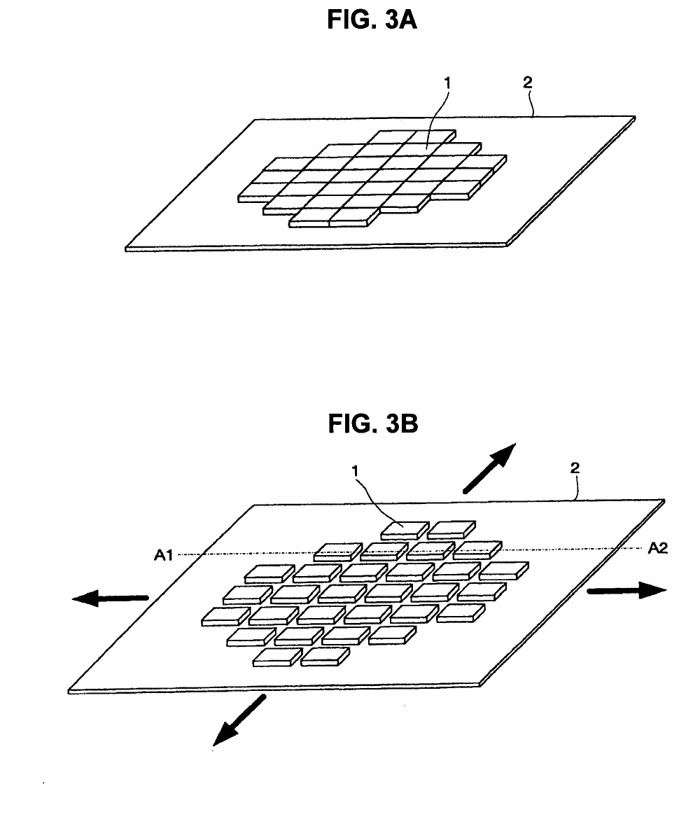

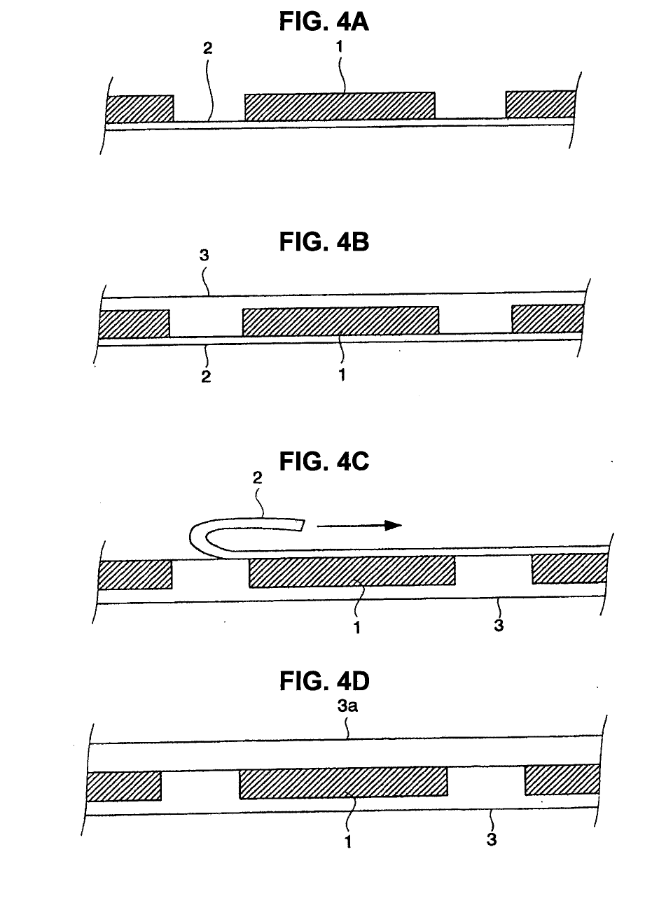

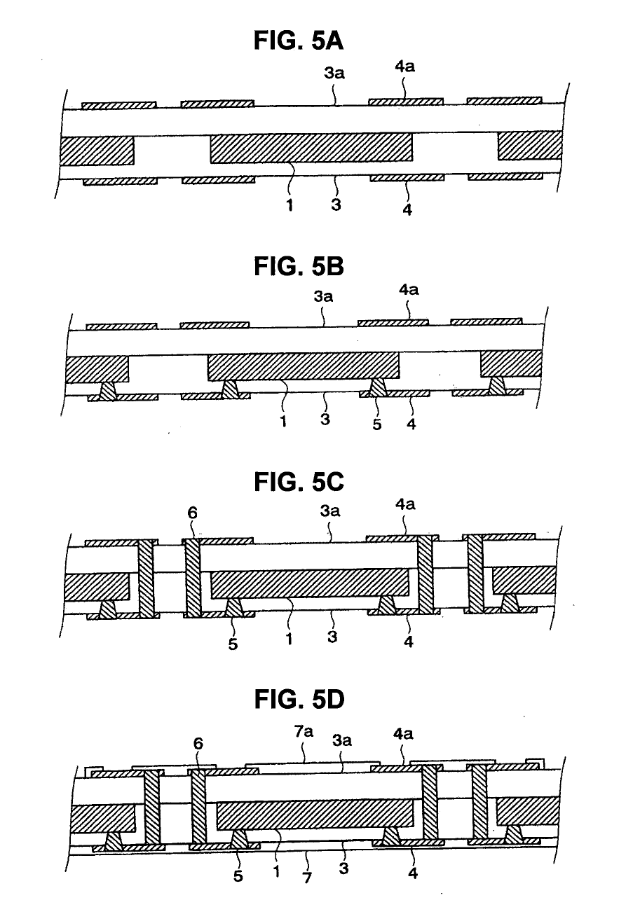

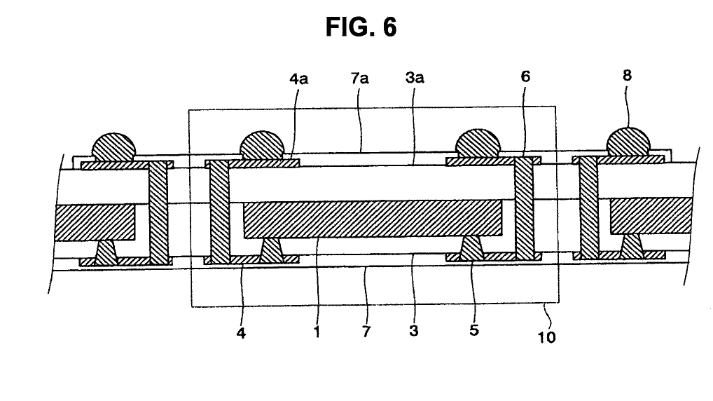

FIG. 2 is a flow chart of a manufacturing process of the semiconductor device according to the first embodiment. FIG. 3A and FIG. 3B are perspective views of semiconductor chips in the manufacturing process of the semiconductor device according to the first embodiment. FIG. 3A and FIG. 3B show a state of an adhesive sheet, on which diced semiconductor wafers (semiconductor chips) are mounted, and a state of the stretched adhesive sheet. FIG. 4A through FIG. 4D, FIG. 5A through FIG. 5D and FIG. 6 are sectional views of a semiconductor chip in a manufacturing process of the semiconductor device according to this embodiment, showing a state of the semiconductor element taken along line A1-A2 of FIG. 3B.

### (1) Arrangement of Semiconductor Chips on Adhesive Sheet (Step S11)

The semiconductor elements 1 (semiconductor chips) are disposed on an adhesive sheet 2. For example, the semiconductor wafer is adhered to the adhesive sheet 2 and diced to form the semiconductor elements 1. The semiconductor elements 1 which are formed by dicing a silicon wafer may be adhered to the adhesive sheet 2.

FIG. 3A is a perspective view showing the semiconductor elements (semiconductor chips) 1 undergone the element forming process. For example, a silicon wafer (semiconductor wafer) having a diameter of about 6 to 8 inches is adhered to the adhesive sheet 2 of a synthetic resin or the like and diced along a dicing line to divide into the individual semiconductor elements (chips) 1. This adhesive sheet 2 is stretchable in a direction perpendicular to the dicing direction of the semiconductor elements 1.

### (2) Tensioning of Adhesive Sheet (Step S12)

The adhesive sheet 2 is tensioned to expand the adhesive sheet 2 so as to provide a space between the semiconductor elements 1.

As shown in FIG. 3B, two-dimensional tension is applied to the adhesive sheet 2 in directions indicated by arrows to form a clearance (gap) between the semiconductor elements 1. As shown in FIG. 4A, the semiconductor elements 1 are disposed with the clearance between them on the tensioned adhesive sheet 2. A tensile force is applied to the adhesive sheet 2 in two directions to separate the semiconductor elements 1 which are disposed two-dimensionally (plane). This tensioning directions can be, for example, directions along the dicing directions. And, tension can also be applied in two directions on the plane of the adhesive sheet 2 independent of the dicing directions to form the clearance between the conductor elements 1 in two directions. The tensioning directions are not necessarily limited if the adhesive sheet 2 is expandable in a plane. And, if the conductor elements 1 are arranged in one-dimensional direction on the adhesive sheet 2, the direction of the tension applied to the adhesive sheet 2 can be limited to one direction only.

The clearance is provided to secure a space (region) allowing the conduction between the upper and lower surfaces of the wiring resin films 3, 3a when the semiconductor wafer is sandwiched by the wiring resin films 3, 3a. For example, the conduction between the upper and lower surfaces of the wiring resin films 3, 3a can be made by forming through holes in the clearance region to pierce through the wiring resin films 3, 3a. A clearance amount can be adjusted by controlling the tension appropriately.

### (3) Adhesion and Curing of First Resin Film (Step S13)

The first resin film is adhered to the semiconductor element 1 and cured. Specifically, the first wiring resin film 3 having a thickness of about 20 to 30 μm is adhered to the surface of the adhesive sheet 2 on which the semiconductor elements 1 are adhered. As a result, the surfaces of the semiconductor elements 1 are coated with the first wiring resin film 3. Then, the wiring resin film 3 is heated to cure (FIG. 4B). As a result, the semiconductor elements 1 are supported by the first wiring resin film 3.

### (4) Removal of Adhesive Sheet, Adhesion of Second Resin Film, and Curing (Steps S14, S15)

The adhesive sheet is removed, and the first resin film 3 is adhered and cured. Specifically, the adhesive sheet 2 is removed from the semiconductor wafers (semiconductor elements 1) (FIG. 4C). Then, the second wiring resin film 3a is adhered to the first wiring resin film 3 which exposes the semiconductor elements 1 as the adhesive sheet 2 is removed. In addition, the second wiring resin film 3a is heated to cure (FIG. 4D). The second wiring resin film 3a may be formed of the same or different material as that of the first wiring resin film 3.

Then, a process of forming a circuit on the wiring resin films 3, 3a will be described with reference to FIG. 5A through FIG. 5D and FIG. 6. FIG. 5A through FIG. 5D and FIG. 6 are sectional views showing a process from the formation of the circuit to mounting of external connection terminals. As shown in FIG. 2, the semiconductor device 10 is produced in order of steps S21 through S25, but this order is not necessarily essential. For example, the order of steps S22, S23 can be changed.

### (5) Formation of First and Second Wiring Patterns on First and Second Resin Films (Step S21)

The first and second wiring patterns 4, 4a are formed on the first and second resin films 3, 3a. For example, a conductive foil such as a copper foil or the like is adhered to the exposed surfaces of the first and second wiring resin films 3, 3a and patterned by etching or the like. As a result, the first and second wiring patterns 4, 4a are formed on the surfaces of the first and second wiring resin films 3, 3a (FIG. 5A).

### (6) Electrical Connection Between First Wiring Pattern and Semiconductor Chip (Step S22)

The first wiring pattern 4 and the semiconductor element 1 are electrically connected. For example, through holes are formed in the wiring pattern 4 and the first wiring resin film 3 by a laser beam to expose a connection electrode (pad) (not shown) of the semiconductor element 1. Besides, the inner surfaces of the through holes are plated, and a connection wiring 5 for electrically connecting the wiring pattern 4 and the pads of the semiconductor elements is formed (FIG. 5B). The connection electrodes are arranged on the surfaces of the semiconductor elements 1 and electrically connected to the internal circuits of the semiconductor elements.

### (7) Electrical Connection of First and Second Wiring Patterns (Step S23)

The wiring patterns 4, 4a are electrically connected. For example, through holes are formed through the first and second wiring resin films 3, 3a by drilling. Then, the inner surfaces of the through holes are plated, and a connection wiring 6 for electrically connecting the wiring patterns 4, 4a is formed (FIG. 5C).

### (8) Formation of Insulating Films (Step S24)

The insulating films 7, 7a such as a resist are formed on the surfaces of the first and second wiring resin films 3, 3a to cover the wiring patterns 4, 4a excepting the external connection terminal-formed region (FIG. 5D).

### (9) Formation of External Connection Terminals Electrically Connected to Second Wiring Pattern (Step S25)

The external connection terminals 8 such as solder balls are connected to the external connection terminal-formed region of the wiring pattern 4a formed on the second wiring resin film 3a. Thus, a wafer-like package is formed (FIG. 6). In FIG. 6, the completed single semiconductor device is a portion surrounded by a dotted line. This wafer-like package is package-diced for each semiconductor element to divide into plural semiconductor devices. FIG. 1 is a sectional view of the divided semiconductor device 10.

According to the production method of the semiconductor package according to this embodiment, the semiconductor wafer is sandwiched from above and below by the wiring resin films 3, 3a to form the substrate in which the semiconductor elements 1 are buried. As a result, the plural semiconductor chips can be collectively handled and fabricated in a state not different from the film substrate, so that productivity can be improved.

A package having a new structure can be obtained by sandwiching the semiconductor elements by the wiring resin films, and the semiconductor device can be made thinner. For example, even when a build-up board is used for the wiring resin film, the semiconductor device can be made thinner. The build-up board is configured by disposing at least a single layer build-up layer on the front and rear surfaces of the insulating substrate which is formed by impregnating a glass fiber nonwoven fabric with a resin such as epoxy resin. The wiring pattern and the connection wiring are appropriately disposed on the build-up layer to electrically connect the semiconductor elements mounted on the build-up board and the external connection terminals attached to the build-up board. For the build-up layer, for example, a wiring resin film which is abbreviated as ABF is used.

The semiconductor elements are sandwiched by the wiring resin films to provide the semiconductor device with a vertically symmetry structure with respect to the silicon. Therefore, a stress applied to the semiconductor device by thermal expansion or the like is easily eased.

At the time of sandwiching the semiconductor wafer by the wiring resin films, tension is applied to the adhesive sheet, on which the semiconductor wafer is mounted, to provide the clearance between the elements and to secure the area where the through holes and the like are formed to make conductive. At the time of sandwiching the silicon wafer between the wiring resin films, the clearance is provided between the elements, so that the external shape of the package becomes not dependent on the external shape of the semiconductor element. For example, for a wafer-level CSP (Chip Size Package), the external size of the package depends on the external size of the semiconductor element, so that there is a possibility that the package size is influenced every time the external size of the semiconductor element is changed depending on a change or the like of the wiring process.

### Second Embodiment

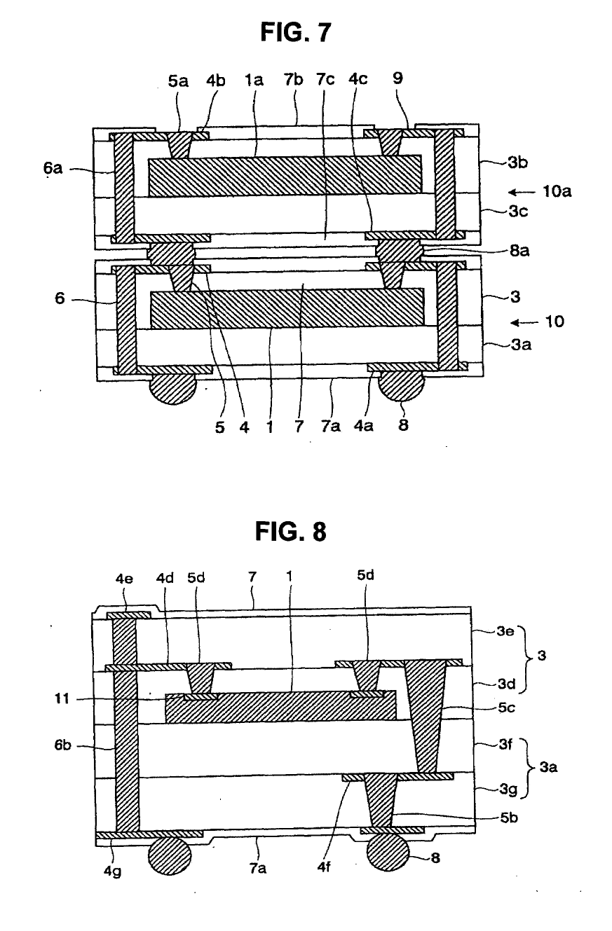

Then, the second embodiment will be described with reference to FIG. 7.

The semiconductor device according to this embodiment has plural packages, in which the semiconductor elements are housed, laminated. FIG. 7 is a sectional view of a semiconductor device described in this embodiment. The semiconductor device according to this embodiment has two packages, in which the semiconductor elements are mounted, laminated, but the number of lamination can also be increased to three or more. In this embodiment, a package 10a is laminated on a package 10.

As shown in FIG. 7, the package 10 is formed of, for example, a silicon semiconductor and has the chip-like semiconductor element 1 having a thickness of, for example, about 60 μm. This semiconductor element 1 is sandwiched between and coated with the first and second wiring resin films 3, 3a. For the first and second wiring resin films 3, 3a, the same material as that of the build-up layer, for example, an epoxy-based thermosetting resin film can be used. The wiring patterns 4, 4a including lands and the like are disposed on the surfaces of the first and second wiring resin films 3, 3a.

The wiring patterns 4, 4a are formed on the surfaces of the first and second wiring resin films 3, 3a. The wiring pattern 4 is formed on the surface of the semiconductor element land electrically connected to a connection electrode (not shown) which is electrically connected to the internal circuit (not shown) of the semiconductor element 1. The external connection terminals 8 such as solder balls are formed on the connection electrode portions of the wiring pattern 4a. The wiring patterns 4, 4a are electrically connected through the connection wiring 6, which is formed of a plated layer or the like buried in the through holes formed in the first wiring resin film 3. As a result, the external connection terminals 8 are electrically connected to the internal circuit of the semiconductor element 1 through the wiring patterns 4, 4a.

The insulating films 7, 7a such as a resist are formed on the surfaces of the first and second wiring resin films 3, 3a to cover the wiring patterns 4, 4a excepting the external connection terminals 8.

The package 10a laminated on the package 10 may have the same or different structure and material as the package 10. But, they have the same structure that the used semiconductor element 1a is sandwiched by the first and second wiring resin films 3b, 3c. The package 10a is disposed on the second wiring resin film 3c, and internal connection terminals 8a such as solder balls are formed on a wiring pattern 4c coated with an insulating film 7c. And, a land region 9 not coated with an insulating film 7b is formed on a wiring pattern 4b of the first wiring resin film 3b.

In this embodiment, additional lamination can be made if required. At that time, the internal connection terminals of the third layer are connected to the land region 9 of the wiring pattern 4c of the second layer.

As described above, the semiconductor device of this embodiment can be made thinner furthermore and formed to be high density by laminating into multiple layers because a package having a new structure can be obtained by sandwiching the semiconductor elements by the wiring resin films.

### Third Embodiment

Then, the third embodiment will be described with reference to FIG. 8.

In this embodiment, the semiconductor elements are sandwiched by a unit of plural wiring resin films and a unit of plural wiring resin films. FIG. 8 is a sectional view of the semiconductor device described in this embodiment. A package using the wiring resin films can be laminated into multiple layers in the same way as a conventional build-up wiring board.

As shown in FIG. 8, the semiconductor device is formed of, for example, a silicon semiconductor, and has a chip-like semiconductor element 1 having a thickness of, for example, about 60 μm. This semiconductor element 1 is sandwiched between and coated with the first and second wiring resin films 3, 3a. For the first and second wiring resin films 3, 3a, the same material as that of the build-up layer, for example, an epoxy-based thermosetting resin film can be used.

The first wiring resin film 3 is comprised of a first layer 3d which directly covers the semiconductor element 1 and a second layer 3e which covers the first layer 3d. The second wiring resin film 3a is comprised of a first layer 3f which directly covers the semiconductor element 1 and a second layer 3g which covers the first layer 3f. A wiring pattern is formed on these wiring resin films 3, 3a, and the internal circuit of the semiconductor element 1 and the external connection terminals 8 are electrically connected through them. Wiring patterns 4d, 4e, 4f, 4g are formed on the first layer 3d and the second layer 3e of the first wiring resin film 3 and the first layer 3f and the second layer 3g of the second wiring resin film 3a, respectively.

The wiring patterns 4e, 4g are electrically connected by a connection wiring 6b buried in the through holes formed through the first and second wiring resin films 3, 3a. The wiring pattern 4d and the wiring pattern 4f are electrically connected by a connection wiring 5c buried in the through holes formed through the first layer 3d of the first wiring resin film and the first layer 3f of the second wiring resin film. The wiring pattern 4f and the wiring pattern 4g are electrically connected by a connection wiring 5b which is formed on the second layer 3g of the second wiring resin film.

The wiring pattern 4d and connection electrodes 11 formed on the semiconductor element 1 are electrically connected by a connection wiring 5d formed on the first layer 3d of the first wiring resin film. External connection terminals 8 such as solder balls are formed on the connection electrode portions of the wiring pattern 4g of the second wiring resin film 3a. The external connection terminals 8 are electrically connected to the internal circuit of the semiconductor element 1 through the wiring patterns 4g, 4d. The insulating films 7, 7a such as a resist are formed on the surfaces of the first and second wiring resin films 3, 3a so as to cover the wiring pattern excepting the external connection terminals 8.

As described above, the semiconductor device of this embodiment can be made thinner furthermore because a package having a new structure can be obtained by sandwiching the semiconductor element by the wiring resin films.

The semiconductor device according to this embodiment can be manufactured by substantially the same manufacturing method of the first embodiment. Specifically, the silicon wafer is sandwiched from above and below by the wiring resin films 3, 3a to form the substrate in which the semiconductor elements 1 are buried. As a result, the plural semiconductor chips can be collectively handled and fabricated, so that productivity can be improved. At the time of sandwiching the silicon wafer between the wiring resin films, the clearance is provided between the elements, so that the external shape of the package does not depend on the external shape of the semiconductor element.

### Other Embodiments

The embodiments of the present invention are not limited to those described above but may be expanded and modified, and the expanded and modified embodiments are also included in the technical scope of the present invention.

1-3. (canceled)

4. A method of manufacturing a semiconductor device, comprising:
applying tension to a stretchable adhesive sheet, on which plural semiconductor chips are disposed, to separate the plural semiconductor chips from one another;
adhering a first resin film to the plural semiconductor chips and curing it;
removing the adhesive sheet from the plural semiconductor chips;
adhering a second resin film to the plural semiconductor chips and curing it; and
forming first and second wiring patterns on the first and second resin films respectively.

5. A method of manufacturing a semiconductor device according to claim 4, wherein the tension on the adhesive sheet is applied in one or two directions.

6. A method of manufacturing a semiconductor device according to claim 4, further comprising:
disposing the plural semiconductor chips on the adhesive sheet.

7. A method of manufacturing a semiconductor device according to claim 4, further comprising:
adhering the adhesive sheet to a semiconductor wafer; and
cutting the semiconductor wafer to form the plural semiconductor chips.

8. A method of manufacturing a semiconductor device according to claim 4, further comprising:
forming a connection wiring which pierces through the first resin film and electrically connects the wiring pattern and the semiconductor chip.

9. A method of manufacturing a semiconductor device according to claim 8,
wherein the formation of the connection wiring includes forming through holes in the first resin film and plating of the formed through holes.

10. A method of manufacturing a semiconductor device according to claim 4, further comprising:
forming a connection wiring which pierces through the first and second resin films and electrically connects the first and second wiring patterns.

11. A method of manufacturing a semiconductor device according to claim 10,
wherein the formation of the connection wiring includes forming through holes in the first and second resin films and plating of the formed through holes.

12. A method of manufacturing a semiconductor device according to claim 4, further comprising:
forming external connection terminals which are disposed on the second resin film and connected to the second wiring pattern.
